(19) United States
(12) Patent Application Publication
(10) Pub. No.: US 2006/0180742 A1
(43) Pub. Date: Aug. 17, 2006

(54) Image sensor

(75) Inventor: Oh-Bong Kwon, Cheongju-si (KR)

Correspondence Address: MORGAN LEWIS & BOCKIUS LLP, 1111 PENNSYLVANIA AVENUE NW, WASHINGTON, DC, 20004, US

(73) Assignee: MagnaChip Semiconductor, Ltd.

(21) Appl. No.: 11/318,641

(22) Filed: Dec. 28, 2005

(30) Foreign Application Priority Data
Feb. 14, 2005 (KR) 2005-0012033

(51) Int. Cl. H01L 27/00

(52) U.S. Cl. 250/208.1

(57) ABSTRACT

An image sensor includes: a pixel array having a plurality of unit pixels arranged in a matrix form of rows and columns; and a plurality of power lines provided on the pixel array for providing the unit pixels with a power supply voltage, wherein the power lines are configured perpendicularly to a scan direction for outputting image data from the pixel array.

### FIELD OF THE INVENTION

The present invention relates to an image sensor; and, more particularly, to an image sensor for improving an image quality by configuring a power line perpendicularly to a scan direction.

### DESCRIPTION OF RELATED ARTS

An image sensor, e.g., a charge coupled device (CCD) and a CMOS image sensor, is a semiconductor device for converting an optical image into an electric signal. The CCD is provided with a plurality of capacitors which are arranged very close one another in order to store electric charge. On the contrary, the CMOS image sensor includes a plurality of unit pixels which is implemented with a single photodiode and three or four transistors for driving the unit pixel.

Though the CMOS image sensor produces an image of low quality compared with that of the CCD, the CMOS image sensor has dominated an image sensor market because of its advantages such as low fabricating cost and low power consumption.

FIG. 1 is a diagram describing a conventional CMOS image sensor which performs a line scan row-by-row.

As shown in FIG. 1, a pixel array PA configured with an N number of pixel columns and an M number of pixel rows to have N×M number of unit pixels UP are provided. Each unit pixel UP provided with a single photodiode and three or four transistors receives a power supply voltage VDD supplied to row-by-row. Therefore, the number of power lines VDD1 to VDDM for providing the power supply voltage VDD is corresponding to the number of the pixel rows, i.e., M.

For example, an image sensor of video graphics array (VGA) includes 640 pixel columns and 480 pixel rows and, therefore, 640 numbers of unit pixels UP concurrently start operation in response to one power line.

FIG. 2 is a schematic circuit diagram modeling one power line configured in the same direction with a line scan direction.

As described in FIG. 2, each unit pixel UP is implemented with a plurality of resistors R and capacitors C corresponding to the number of the pixel columns, i.e., N.

When the power supply voltage VDD of 2.5V is used for driving the CMOS image sensor, a level of the power supply voltage VDD at the first column A is still 2.5V. However, as the line scan is performed, the level of the power supply voltage VDD decreases. The level of the power supply voltage VDD of the Nth column C drops to 2.45V.

Abovementioned voltage drop could cause a serious problem under a low operation voltage circumstance. That is, when the power supply voltage VDD lower than 2.5V is used, an amount of the power supply voltage VDD supplied to the unit pixel is too small to drive the unit pixel properly by reaching to the Nth column. Therefore, an image quality of unit pixels near to the Nth column is degraded. Further, as a resolution of the image sensor increases, the number of unit pixels in a corresponding line also increases. In this case, the problem caused by the voltage drop becomes serious.

### SUMMARY OF THE INVENTION

It is, therefore, an object of the present invention to provide an image sensor for improving an image quality by configuring a power line perpendicularly to a scan direction.

In accordance with an aspect of the present invention, there is provided an image sensor, including: a pixel array having a plurality of unit pixels arranged in a matrix form of rows and columns; and a plurality of power lines provided on the pixel array for providing the unit pixels with a power supply voltage, wherein the power lines are configured perpendicularly to a scan direction for outputting an image data from the pixel array.

In accordance with another aspect of the present invention, there is provided a method for configuring a plurality of power lines on a pixel array of an image sensor, the method including: forming the pixel array having a plurality of unit pixels arranged in a matrix form of rows and columns; and configuring the power lines on the pixel array for providing the unit pixels with a power supply voltage, wherein the power lines are configured perpendicularly to a scan direction for outputting an image data from the pixel array.

### BRIEF DESCRIPTION OF THE DRAWINGS

The above and other objects and features of the present invention will become apparent from the following description of preferred embodiments taken in conjunction with the accompanying drawings, in which:

FIG. 1 is a diagram describing a conventional CMOS image sensor which performs a line scan row-by-row;

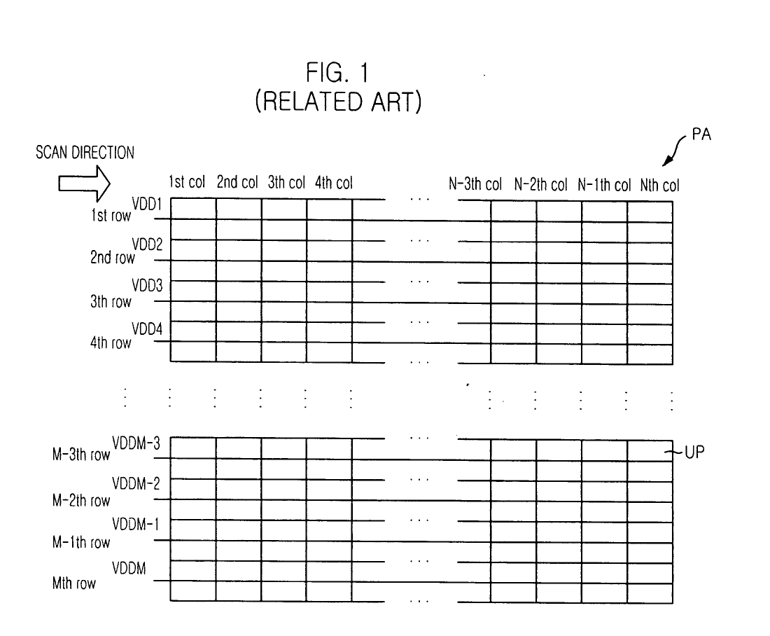

FIG. 2 is a schematic circuit diagram modeling one power line configured in the same direction with a line scan direction;

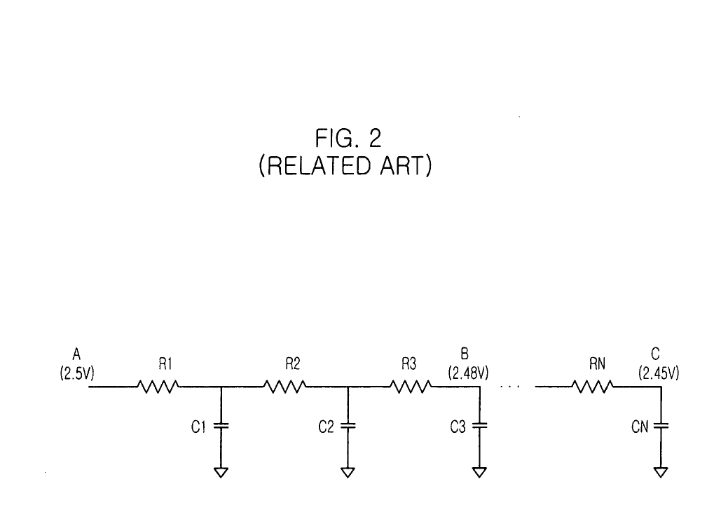

FIG. 3 is a diagram showing a CMOS image sensor in accordance with an embodiment of the present invention which performs a line scan row-by-row;

FIG. 4 is a schematic circuit diagram modeling one power line configured perpendicularly to the scan direction; and

FIG. 5 is a diagram describing a CMOS image sensor in accordance with an embodiment of the present invention which performs a line scan column-by-column.

### DETAILED DESCRIPTION OF THE INVENTION

Hereinafter, an image sensor in accordance with the present invention will be described in detail referring to the accompanying drawings.

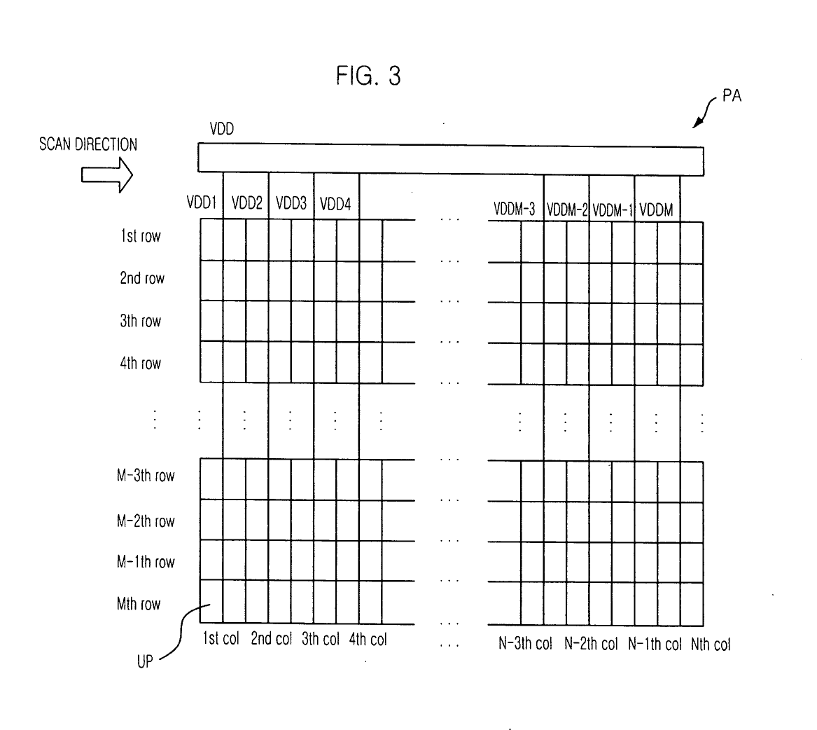

FIG. 3 is a diagram showing a CMOS image sensor in accordance with an embodiment of the present invention which performs a line scan row-by-row.

Referring to FIG. 3, a pixel array PA configured with an N number of pixel columns and an M number of pixel rows to have N×M number of unit pixels UP are provided. Each unit pixel UP provided with a single photodiode and three or four transistors receives a power supply voltage VDD.

The power line VDD1 to VDDN is configured perpendicularly to a scan direction for outputting an image data from the pixel array PA. In other words, when the CMOS image sensor performs a line scan in a row direction, the power supply voltage VDD is supplied column-by-column. In this case, the number of power line VDD1 to VDDN is corresponding to the number of the pixel columns, i.e., N.

Though it is not described in FIG. 3, the CMOS image sensor further includes a data line for outputting the image data from the plurality of unit pixels. The power line VDD1 to VDDN is configured in the same direction with the data line. That is, when the CMOS image sensor performs the line scan in the row direction, the image data in a single row is scanned column-by-column and, then, outputted through the data line configured in a column direction.

All of the power lines VDD1 to VDDN receives the power supplied voltage VDD from a main power line VDD_M arranged in the row direction. Therefore, the main power line VDD_M and the power line VDD1 to VDDN are arranged perpendicularly to each other.

Meanwhile, although the single main power line VDD_M is provided in the embodiment described in FIG. 3, a plurality of main power lines can be included in another embodiment of the present invention. In this case, each main power line VDD_M is shared by a predetermined number of power lines in order to supply the power supply voltage VDD to the predetermined number of power lines.

As abovementioned, the power lines VDD1 to VDDN is configured perpendicularly to the scan direction, only one unit pixel UP among the unit pixels connected to one power line is connected to the power line at one time. That is, because the line scan is performed row-by-row, the unit pixel UP corresponding to the row which is currently scanned is connected to the power line. Therefore, a voltage drop is not occurred during a scan operation.

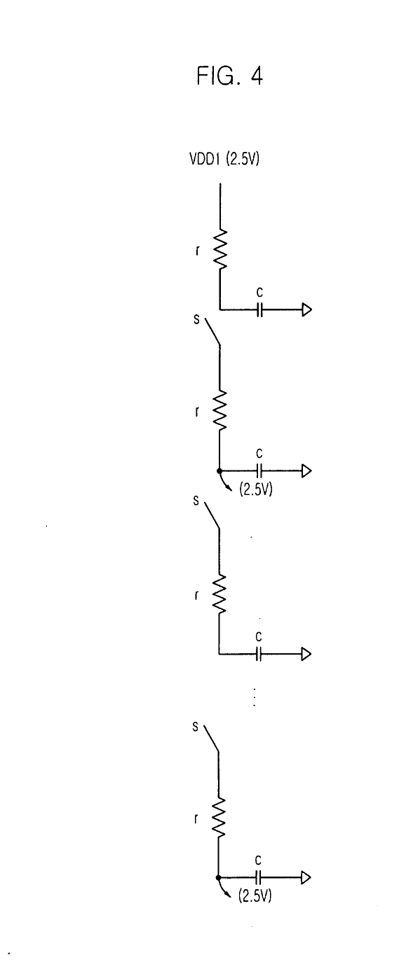

FIG. 4 is a schematic circuit diagram modeling the power line configured perpendicularly to the scan direction.

As shown, each unit pixel UP is implemented with a plurality of resistors R and capacitors C corresponding to the number of the pixel rows, i.e., M.

As abovementioned, the unit pixels in one power line, i.e., in one column line, connected to the power line when the scanning operation is performed to the corresponding row. Therefore, the voltage drop is not occurred and, thus, every unit pixels in the same power line receives the power supply voltage VDD of 2.5V when the level of the power supply voltage VDD is 2.5V.

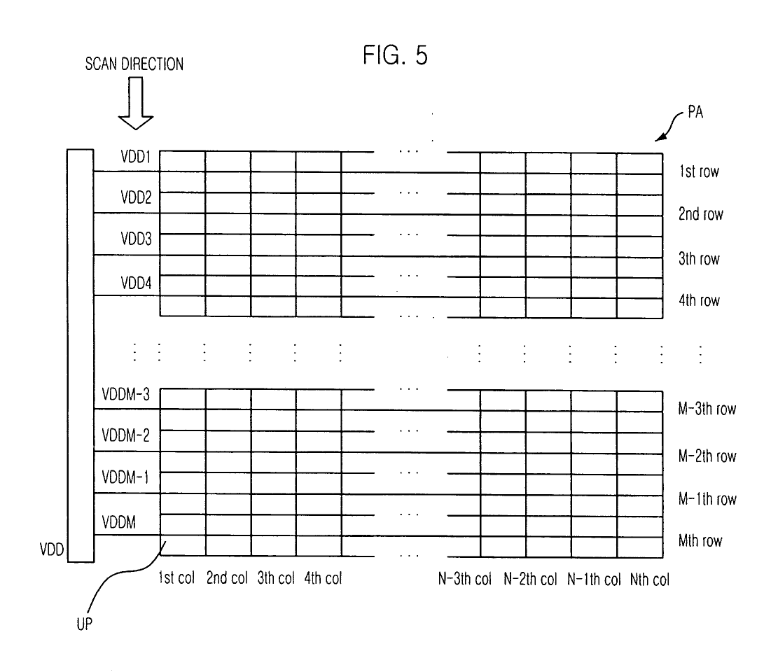

FIG. 5 is a diagram describing a CMOS image sensor in accordance with an embodiment of the present invention which performs a line scan column-by-column.

Referring to FIG. 5, a pixel array PA configured with an N number of pixel columns and an M number of pixel rows to have N×M number of unit pixels UP are provided. Each unit pixel UP provided with a single photodiode and three or four transistors receives a power supply voltage VDD.

The power line VDD1 to VDDM is configured perpendicularly to a scan direction for outputting an image data from the pixel array PA. In other words, when the CMOS image sensor performs a line scan in a column direction, the power supply voltage VDD is supplied row-by-row. In this case, the number of power line VDD1 to VDDM is corresponding to the number of the pixel rows, i.e., M.

Though it is not described in FIG. 5, the CMOS image sensor further includes a data line for outputting the image data from the plurality of unit pixels. The power line VDD1 to VDDM is configured in the same direction with the data line. That is, when the CMOS image sensor performs the line scan in the column direction, the image data in a single column is scanned row-by-row and, then, outputted through the data line configured in a row direction.

All of the power lines VDD1 to VDDM receives the power supplied voltage VDD from a main power line VDD_M arranged in the column direction. Therefore, the main power line VDD_M and the power line VDD1 to VDDM are arranged perpendicularly to each other.

Meanwhile, although the single main power line VDD_M is provided in the embodiment described in FIG. 5, a plurality of main power lines can be included in another embodiment of the present invention. In this case, each main power line VDD_M is shared by a predetermined number of power lines in order to supply the power supply voltage VDD to the predetermined number of power lines.

As abovementioned, the power lines VDD1 to VDDM is configured perpendicularly to the scan direction, only one unit pixel UP among the unit pixels connected to one power line is connected to the power line at one time. That is, because the line scan is performed column-by-column, the unit pixel UP corresponding to the column which is currently scanned is connected to the power line. Therefore, a voltage drop is not occurred during a scan operation.

Further, in abovementioned embodiments, the present invention is explained by taking the CMOS image sensor as an example. However, the present invention can be also applied to image sensors of active type.

The present invention provides an image sensor for improving an image quality by configuring a power line perpendicularly to a scan direction.

The present application contains subject matter related to Korean patent application No. 2005-12033, filed in the Korean Patent Office on Feb. 14, 2005, the entire contents of which being incorporated herein by reference.

While the present invention has been described with respect to the particular embodiments, it will be apparent to those skilled in the art that various changes and modifications may be made without departing from the spirit and scope of the invention as defined in the following claims.

What is claimed is:

1. An image sensor, comprising:
a pixel array having a plurality of unit pixels arranged in a matrix form of rows and columns; and
a plurality of power lines provided on the pixel array for providing the unit pixels with a power supply voltage,
wherein the power lines are configured perpendicularly to a scan direction for outputting image data from the pixel array.

2. The image sensor as recited in claim 1, wherein the scan direction is a row direction and the power lines are configured in a column direction.

3. The image sensor as recited in claim 2, wherein the power lines are configured in the same direction with data lines for outputting the image data.

4. The image sensor as recited in claim 2, further comprising a single main power line configured perpendicularly to the power lines in order to provide the power lines with the power supply voltage.

5. The image sensor as recited in claim 2, further comprising a plurality of main power lines, each main power line shared by a predetermined number of power lines in order to provide the predetermined number of power lines with the power supply voltage.

6. The image sensor as recited in claim 1, wherein the scan direction is a column direction and the power lines are configured in a row direction.

7. The image sensor as recited in claim 6, wherein the power lines are configured in the same direction with a data line for outputting the image data.

8. The image sensor as recited in claim 6, further comprising a single main power line configured perpendicularly to the power lines in order to provide the power lines with the power supply voltage.

9. The image sensor as recited in claim 6, further comprising a plurality of main power lines, each main power line shared by a predetermined number of power lines in order to provide the predetermined number of power lines with the power supply voltage.

10. A method for configuring a plurality of power lines on a pixel array of an image sensor, the method comprising:
forming the pixel array having a plurality of unit pixels arranged in a matrix form of rows and columns; and
configuring the power lines on the pixel array for providing the unit pixels with a power supply voltage,
wherein the power lines are configured perpendicularly to a scan direction for outputting image data from the pixel array.

11. The method as recited in claim 10, wherein the scan direction is a row direction and the power lines are configured in a column direction.

12. The method as recited in claim 11, wherein the power lines are configured in the same direction with a data line for outputting the image data.

13. The method as recited in claim 11, further comprising a single main power line configured perpendicularly to the power lines in order to provide the power lines with the power supply voltage.

14. The method as recited in claim 11, further comprising a plurality of main power lines, each main power line shared by a predetermined number of power lines in order to provide the predetermined number of power lines with the power supply voltage.

15. The method as recited in claim 10, wherein the scan direction is a column direction and the power lines are configured in a row direction.

16. The method as recited in claim 15, wherein the power lines are configured in the same direction with a data line for outputting the image data.

17. The method as recited in claim 15, further comprising a single main power line configured perpendicularly to the power lines in order to provide the power lines with the power supply voltage.

18. The method as recited in claim 15, further comprising a plurality of main power lines, each main power line shared by a predetermined number of power lines in order to provide the predetermined number of power lines with the power supply voltage.
